(19) United States
(12) Patent Application Publication
(10) Pub. No.: US 2024/0326449 A1
(43) Pub. Date: Oct. 3, 2024

(54) LIQUID EJECTING APPARATUS

(71) Applicant: SEIKO EPSON CORPORATION, Tokyo (JP)

(72) Inventor: Shinji FUJIMAKI, Matsumoto (JP)

(21) Appl. No.: 18/616,239

(22) Filed: Mar. 26, 2024

(30) Foreign Application Priority Data
Mar. 28, 2023 (JP) 2023-051086

(51) Int. Cl. B41J 2/17; B41J 2/175; H05K 7/20

(52) U.S. Cl. CPC B41J 2/1714; B41J 2/175; H05K 7/20145

(57) ABSTRACT

A liquid ejecting apparatus includes a print head that ejects liquid onto a medium, a liquid storage section that stores the liquid, a tube that supplies the liquid from the liquid storage section to the print head, a duct in which gas flows, and a fan that forms a flow of the gas in the duct. At least a portion of the tube is disposed in the duct.

The present application is based on, and claims priority from JP Application Serial Number 2023-051086, filed Mar. 28, 2023, the disclosure of which is hereby incorporated by reference herein in its entirety.

### BACKGROUND

### 1. Technical Field

The present disclosure relates to a liquid ejecting apparatus.

### 2. Related Art

JP-A-2022-102320 discloses a liquid ejecting apparatus that supplies, from each ink storage section to a line head via a tube, ink to be ejected from the line head.

However, in the liquid ejecting apparatus disclosed in JP-A-2022-102320, the temperature of the ink may increase due to warming of the tube, and the characteristics of the ink may change due to the increase in the temperature of the ink.

### SUMMARY

According to an aspect of the present disclosure, a liquid ejecting apparatus includes a print head that ejects liquid onto a medium, a liquid storage section that stores the liquid, a tube that supplies the liquid from the liquid storage section to the print head, a duct in which gas flows, and a fan that forms a flow of the gas in the duct, and at least a portion of the tube is disposed in the duct.

### BRIEF DESCRIPTION OF THE DRAWINGS

FIG. 1 is a diagram illustrating a functional configuration of a liquid ejecting apparatus.

FIG. 2 is a diagram for explaining a schematic structure of an ejecting section.

FIG. 3 is a diagram illustrating a schematic structure of the liquid ejecting apparatus.

FIG. 4 is an exterior perspective view of the liquid ejecting apparatus.

FIG. 5 is a diagram for explaining a main part of the liquid ejecting apparatus.

FIG. 6 is a diagram for explaining the main part of the liquid ejecting apparatus.

### DESCRIPTION OF EMBODIMENTS

Embodiments of the present disclosure are described with reference to the drawings. The drawings used are for convenience of explanation. The embodiments described below do not unduly limit the content of the present disclosure described in the claims. In addition, not all of configurations described below are necessarily essential in the present disclosure.

### 1. Functional Configuration of Liquid Ejecting Apparatus

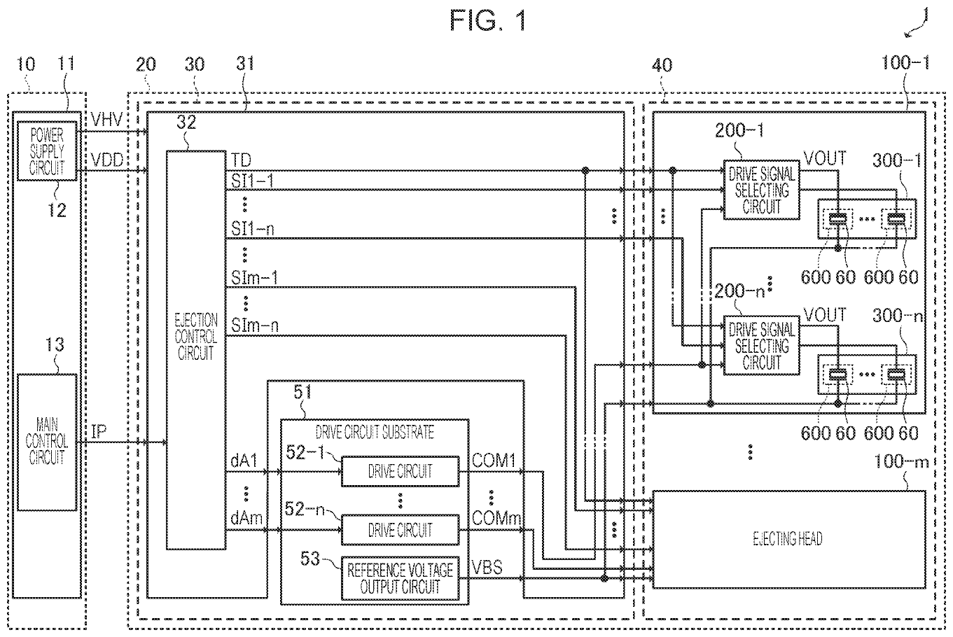

FIG. 1 is a diagram illustrating a functional configuration of a liquid ejecting apparatus 1. A case where the liquid ejecting apparatus 1 is a so-called ink jet printer or the like that forms a desired image on a medium is described below. The liquid ejecting apparatus 1 may be any one of liquid ejecting apparatuses that eject various types of liquid onto the medium, and are a color material ejecting apparatus that is used for manufacturing a color filter for a liquid crystal display or the like, an electrode material ejecting apparatus that is used for forming an electrode for an organic electro-luminescence (EL) display or the like, a biological organic matter ejecting apparatus that is used for forming a biochip, a three-dimensional modeling apparatus that is used for forming a three-dimensional structure, and the like.

As illustrated in FIG. 1, the liquid ejecting apparatus 1 includes a control mechanism 10 and a print head 20.

The control mechanism 10 includes a wiring substrate 11, a power supply circuit 12 mounted on the wiring substrate 11, and a main control circuit 13. The control mechanism 10 generates a power supply voltage for driving the print head 20 and a control signal for controlling an operation of the print head 20, and outputs the power supply voltage and the control signal to the print head 20.

Specifically, a commercial voltage is input to the power supply circuit 12 from a commercial alternate-current power supply (not illustrated) disposed outside the liquid ejecting apparatus 1. The power supply circuit 12 generates, based on the input commercial voltage, various power supply voltages to be used by the liquid ejecting apparatus 1. For example, the power supply circuit 12 generates, based on the input commercial voltage, a direct-current voltage VHV having a voltage value of 42 V and a direct-current voltage VDD having a voltage value of 5 V. The power supply circuit 12 includes, for example, an AC/DC converter and a DC/DC converter. The AC/DC converter is a flyback circuit or the like that converts the commercial voltage, which is an alternate-current voltage, into a direct-current voltage. The DC/DC converter converts a voltage value of the direct-current voltage output by the AC/DC converter. The various power supply voltages generated by the power supply circuit 12 and including the voltages VHV and VDD are supplied to the print head 20. As a result of the supply of the various supply voltages to the print head 20, the print head 20 operates to eject ink that is an example of liquid. The power supply circuit 12 may generate a power supply voltage having a desired voltage value and to be used in each component of the liquid ejecting apparatus 1 including the control mechanism 10 and the print head 20, in addition to the voltages VHV and VDD, and may supply the generated power supply voltage to each corresponding configuration of the liquid ejecting apparatus 1.

An image signal is input to the main control circuit 13 from an external apparatus such as a host computer disposed outside the liquid ejecting apparatus 1 via an interface circuit not illustrated. The main control circuit 13 generates an image information signal IP as a control signal for forming an image corresponding to the input image signal on the medium and outputs the image information signal IP to a corresponding configuration of the liquid ejecting apparatus 1. Specifically, after performing predetermined image processing on the input image signal, the main control circuit 13 outputs, to the print head 20, the signal subjected to the image processing as the image information signal IP. The image processing performed by the main control circuit 13 includes, for example, color conversion processing of converting the input image signal into color information of red, green, and blue colors and converting the color information into color information corresponding to a color of the ink to be ejected from the liquid ejecting apparatus 1, and halftone processing of binarizing the color information. The image processing performed by the main control circuit 13 is not limited to the color conversion processing and the halftone processing described above.

The main control circuit 13 generates, based on the input image signal, a transport control signal for transporting the medium on which the image based on the image signal is to be formed. The main control circuit 13 outputs the generated transport control signal to a transport unit 70 described later. The transport of the medium on which the ink ejected from the print head 20 lands is controlled based on the transport control signal. The main control circuit 13 may be one or a plurality of semiconductor apparatuses having a plurality of functions, and may include, for example, a system on a chip (SoC).

As described above, in the control mechanism 10, the power supply circuit 12 generates the voltages VHV and VDD as power supply voltages for driving the print head 20, and the main control circuit 13 generates the image information signal IP for controlling the operation of the print head 20. The ink is ejected from the print head 20 by supplying, to the print head 20, the voltages VHV and VDD and the image information signal IP generated by the control circuit 10.

The print head 20 includes an ejection control module 30 and an ejection module 40.

The ejection control module 30 includes an ejection control circuit 32 mounted on an ejection control substrate 31, drive circuits 52-1 to 52-n mounted on a drive circuit substrate 51, and a reference voltage output circuit 53 mounted on the drive circuit substrate 51.

The image information signal IP output by the main control circuit 13 is input to the ejection control circuit 32. The ejection control circuit 32 generates, based on the input image information signal IP, an ejection timing signal TD for controlling the ejection of the ink from the print head 20, and print data signals SI1-1 to SI1-n, . . . , and Sim-1 to Sim-n. The ejection control module 30 outputs, to the ejection module 40, the ejection timing signal TD and the print data signals SI1-1 to SI1-n, . . . , and Sim-1 to Sim-n output by the ejection control circuit 32.

The ejection control circuit 32 generates basic drive signals dA1 to dAm based on the image information signal IP input from the main control circuit 13 and outputs the generated basic drive signals dA1 to dAm to the drive circuit substrate 51.

The basic drive signal dA1 output by the ejection control circuit 32 is input to the drive circuit 52-1 mounted on the drive circuit substrate 51. The drive circuit 52-1 converts the input basic drive signal dA1 into an analog signal and amplifies the converted analog signal based on the voltage VHV to generate a drive signal COM1. Similarly, the drive circuit 52-i (i is any one of 1 to m) converts the input basic drive signal dAi into an analog signal and amplifies the converted analog signal based on the voltage VHV to generate a drive signal COMi. That is, the basic drive signal dA1 is a signal defining a signal waveform of the drive signal COM1, and the basic drive signal dAi is a signal defining a signal waveform of the drive signal COMi. The reference voltage output circuit 53 mounted on the drive circuit substrate 51 increases or reduces the voltage VDD or the voltage VHV to generate a reference voltage signal VBS.

The drive signals COM1 to COMm generated by the drive circuits 52-1 to 52-m and the reference voltage signal VBS generated by the reference voltage output circuit 53 are output from the drive circuit substrate 51. The drive signals COM1 to COMm and the reference voltage signal VBS output from the drive circuit substrate 51 are transmitted through the ejection control substrate 31 and output to the ejection module 40 from the ejection control module 30.

The ejection module 40 includes ejecting heads 100-1 to 100-m. Each of the ejecting heads 100-1 to 100-m includes drive signal selecting circuits 200-1 to 200-n and head chips 300-1 to 300-n corresponding to the drive signal selecting circuits 200-1 to 200-n, respectively.

The ejection timing signal TD, the print data signal SI1-1, and the drive signal COM1 are input to the drive signal selecting circuit 200-1 included in the ejecting head 100-1. The drive signal selecting circuit 200-1 included in the ejecting head 100-1 generates a drive signal VOUT corresponding to each of a plurality of ejecting sections 600 included in the head chip 300-1 included in the ejecting head 100-1 by selecting or unselecting a drive waveform included in the drive signal COM1 based on the print data signal SI1-1 at a timing defined by the ejection timing signal TD. The drive signal selecting circuit 200-1 included in the ejecting head 100-1 supplies the generated drive signal VOUT to one end of each of piezoelectric elements 60 included in the ejecting sections 600 corresponding to the drive signal selecting circuit 200-1. In this case, the reference voltage signal VBS is supplied to the other end of each of the piezoelectric elements 60. Each of the piezoelectric elements 60 is driven based on a potential difference between the drive signal VOUT supplied to the one end and the reference voltage signal VBS supplied to the other end. As the piezoelectric elements 60 are driven, ink is ejected from the ejecting sections 600.

Similarly, the ejection timing signal TD, the print data signal SI1-n, and the drive signal COM1 are input to the drive signal selecting circuit 200-n included in the ejecting head 100-1. The drive signal selecting circuit 200-n included in the ejecting head 100-1 generates a drive signal VOUT corresponding to each of a plurality of ejecting sections 600 included in the head chip 300-n included in the ejecting head 100-1 by selecting or unselecting the drive waveform included in the drive signal COM1 based on the print data signal SI1-n at a timing defined by the ejecting timing signal TD. The drive signal selecting circuit 200-n included in the ejecting head 100-1 supplies the generated drive signal VOUT to one end of each of piezoelectric elements 60 included in the ejecting sections 600 corresponding to the drive signal selecting circuit 200-n. In this case, the reference voltage signal VBS is supplied to the other end of each of the piezoelectric elements 60. Each of the piezoelectric elements 60 is driven based on a potential difference between the drive signal VOUT supplied to the one end and the reference voltage signal VBS supplied to the other end. As the piezoelectric elements 60 are driven, ink is ejected from the ejecting sections 600.

A configuration and operation of the ejecting head 100-1 are identical or similar to configurations and operations of the ejecting heads 100-2 to 100-m, except that the signals input to the ejecting head 100-1 are different from the signals input to the ejecting head 100-2 to 100-m. Therefore, the configurations and operations of the ejecting heads 100-2 to 100-m will not be described. In the following description, when the ejecting heads 100-1 to 100-6 do not need to be distinguished, the ejecting heads 100-1 to 100-6 may be merely referred to as ejecting heads 100. In the following description, it is assumed that the ejecting timing signal TD, print data signals SI-1 to SI-m as the print data signals SI1-1 to SI1-n, . . . , and Sim-1 to Sim-n, drive signals COM as the drive signals COM1 to COMm, and the reference voltage signal VBS are input to the ejecting heads 100, and the drive signals COM are output by drive circuits 52 as the drive circuits 52-1 to 52-m.

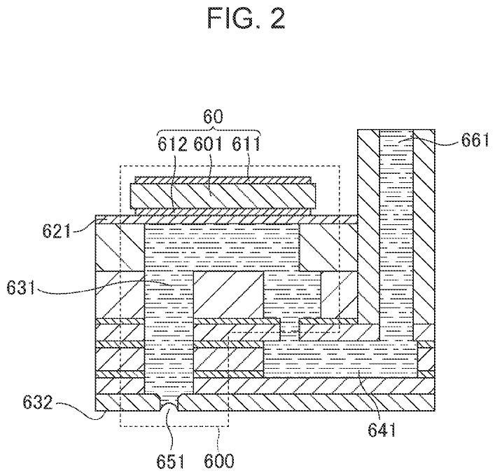

Next, an example of a structure of each of the ejecting sections 600 included in each of the head chips 300-1 to 300-n included in each of the ejecting heads 100-1 to 100-m is described. FIG. 2 is a diagram for explaining a schematic structure of the ejecting section 600. FIG. 2 illustrates a nozzle plate 632, a reservoir 641, and a supply port 661, in addition to the ejecting section 600.

As illustrated in FIG. 2, the ejecting section 600 includes a piezoelectric element 60, a vibration plate 621, a cavity 631, and a nozzle 651. The piezoelectric element 60 includes electrodes 611 and 612 and a piezoelectric body 601 sandwiched between the electrodes 611 and 612. A drive signal VOUT is supplied to the electrode 611. The reference voltage signal VBS is supplied to the electrode 612. The piezoelectric element 60 is driven in such a way that a central portion of the piezoelectric element 60 deforms according to a potential difference between the drive signal VOUT supplied to the electrode 611 and the reference voltage signal VBS supplied to the electrode 612.

The vibration plate 621 is located beneath the piezoelectric element 60 in FIG. 2. In other words, the piezoelectric element 60 is formed on an upper surface of the vibration plate 621 in FIG. 2. The vibration plate 621 deforms in a vertical direction as the piezoelectric element 60 is driven in the vertical direction.

The cavity 631 is located under the vibration plate 621 in FIG. 2. Ink is supplied into the cavity 631 from the reservoir 641. The ink is introduced into the reservoir 641 through the supply port 661. That is, the ink supplied from the supply port 661 is stored in the cavity 631. The internal capacity of the cavity 631 increases or decreases as the vibration plate 621 deforms in the vertical direction. That is, the vibration plate 621 functions as a diaphragm that changes the internal capacity of the cavity 631, and the cavity 631 functions as a pressure chamber in which internal pressure changes as the vibration plate 621 deforms in the vertical direction.

The nozzle 651 is an opening disposed in the nozzle plate 632 and communicates with the cavity 631. The ink stored in the cavity 631 is ejected from the nozzle 651 according to a change in the internal capacity of the cavity 631.

Specifically, in the ejecting section 600, when the piezoelectric element 60 is driven to be bent upward, the vibration plate 621 deforms upward. As a result of the upward deformation of the vibration plate 621, the internal capacity of the cavity 631 increases and the ink stored in the reservoir 641 is drawn into the capacity 631. On the other hand, when the piezoelectric element 60 is driven to be bent downward, the vibration plate 621 deforms downward. As a result of the downward deformation of the vibration plate 621, the internal capacity of the cavity 631 decreases and the ink in an amount corresponding to the decrease in the internal capacity of the cavity 631 is ejected from the nozzle 651.

The structure of the piezoelectric element 60 is not limited to the structure illustrated in FIG. 2 as long as the piezoelectric element 60 is driven according to the drive signal VOUT and the reference voltage signal VBS and the ink can be ejected from the nozzle 651 due to the driving of the piezoelectric element 60.

That is, the print head 20 according to the present embodiment includes the nozzle plate 632 in which the nozzles 651 from which the ink is ejected are formed, and the drive circuits 52 that output drive signals COM on which drive signals VOUT for ejecting the ink from the nozzles 651 are based. The head chips 300-1 to 300-n each having the plurality of ejecting sections 600 have the same configuration or similar configurations. Therefore, in the following description, when the head chips 300-1 to 300-n do not need to be distinguished, the head chips 300-1 to 300-n may be merely referred to as head chips 300.

### 2. Structure of Liquid Ejecting Apparatus

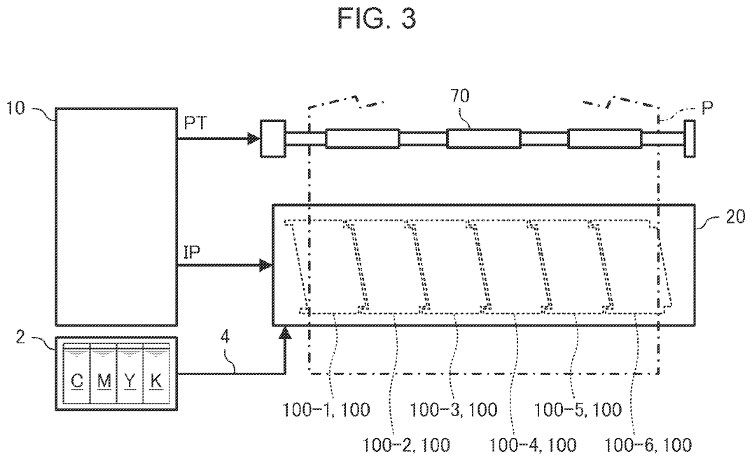

Next, a schematic structure of the liquid ejecting apparatus 1 is described. FIG. 3 is a diagram illustrating the schematic structure of the liquid ejecting apparatus 1. In the following description, it is assumed that the print head 20 includes six ejecting heads 100, which are ejecting heads 100-1 to 100-6.

As illustrated in FIG. 3, the liquid ejecting apparatus 1 includes the transport unit 70, a liquid storage section 2, and a tube 4, in addition to the control mechanism 10 and the print head 20 described above. The transport unit 70 transports a medium P on which the ink ejected from the print head 20 lands. The ink to be ejected from the print head 20 is stored in the liquid storage section 2. The tube 4 supplies the ink from the liquid storage section 2 to the print head 20.

The control mechanism 10 includes the power supply circuit 12 and the main control circuit 13 as described above. The control mechanism 10 controls an operation of the liquid ejecting apparatus 1 including the print head 20. The control mechanism 10 may include a storage circuit and an interface circuit, in addition to the power supply circuit 12 and the main control circuit 13. The storage circuit stores various types of information of the liquid ejecting apparatus 1. The interface circuit communicates with an external apparatus such as the host computer disposed outside the liquid ejecting apparatus 1.

The control mechanism 10 receives an image signal input from the external apparatus disposed outside the liquid ejecting apparatus 1, generates, based on the received image signal, a control signal PT corresponding to the transport control signal for controlling the transport of the medium P, and outputs the generated control signal PT to the transport unit 70. As a result of the output of the control signal PT to the transport unit 70, the transport unit 70 transports the medium P. The transport unit 70 includes a roller (not illustrated) for transporting the medium P and a motor for rotating the roller.

In the liquid storage section 2, the ink to be ejected from the print head 20 is stored. For example, in the liquid storage section 2, ink of four colors, cyan C, magenta M, yellow Y, and black K is stored. The ink stored in the liquid storage section 2 is supplied to the ejecting heads 100-1 to 100-6 included in the print head 20 through the tube 4. The number of containers that are included in the liquid storage section 2 and in which the ink is stored is not limited to 4. In the liquid storage section 2, ink of colors other than cyan C, magenta M, yellow Y, and black K may be stored.

The print head 20 is a line head having a length equal to or longer than a width of the medium P. For example, the ejecting heads 100-1 to 100-6 included in the print head 20 are arranged side by side in the width direction of the medium P in the order of the ejecting heads 100-1, 100-2, 100-3, 100-4, 100-5, and 100-6. In this case, the ejecting heads 100-1 to 100-6 are arranged in such a way that a distance from an end of the ejecting head 100-1 to an end of the ejecting head 100-6 is equal to or longer than the width of the medium P to be transported. The print head 20 distributes the ink supplied from the liquid storage section 2 to each of the ejecting heads 100-1 to 100-6 and operates based on the image information signal IP input from the control mechanism 10. As a result, the print head 20 ejects the ink onto a desired position on the medium P. The number of ejecting heads 100 included in the print head 20 is not limited to 6 and may be 5 or less or 7 or more.

As described above, in the liquid ejecting apparatus 1, the control mechanism 10 generates the image information signal IP based on the image signal input from the external apparatus and outputs the image information signal IP to the print head 20. Then, the print head 20 ejects the ink onto the medium P at a timing according to the image information signal IP input from the control mechanism 10. As a result, the ink ejected by the print head 20 lands on a desired position on the medium P and a desired image is formed on the medium P.

In the following description, it is assumed that the liquid ejecting apparatus 1 is a so-called line printing type liquid ejecting apparatus that forms a desired image on the medium P by causing the ejecting heads 100 to eject the ink onto the medium P transported by the transport unit 70, and the ejecting heads 100 are arranged side by side in such a way that the distance from the end of the ejecting head 100-1 to the end of the ejecting head 100-6 is equal to or longer than the width of the medium P. However, the liquid ejecting apparatus 1 is not limited to the so-called line printing type liquid ejecting apparatus and may be a so-called serial type liquid ejecting apparatus in which a print head 20 is mounted on a carriage that is movable in a scan direction, and the carriage is moved as the medium P is transported in such a way that ink lands on a desired position on the medium P.

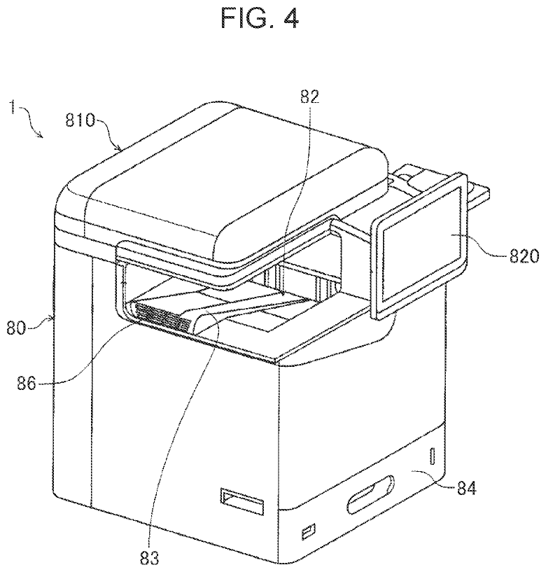

FIG. 4 is an exterior perspective view of the liquid ejecting apparatus 1. The liquid ejecting apparatus 1 includes a housing 80 as illustrated in FIG. 4.

A scanner unit 810 is disposed on an upper portion of the housing 80. An operation panel 820 is disposed on a front surface of the housing 80. The housing 80 includes a discharge tray 82 for taking out a medium discharged from inside the housing 80. A medium cassette 84 for storing a medium is disposed in a lower portion of the housing 80.

A protrusion 83 that protrudes upward is formed in the discharge tray 82 and extends in a direction in which a medium is discharged. Due to the protrusion 83, the medium held on the discharge tray 82 becomes bent in the width direction of the medium, curling of the medium on the discharge tray 82 is suppressed, and alignment of the medium is improved. An air inlet 86 for drawing outside air into the duct 6 is provided at an end of the discharge tray 82.

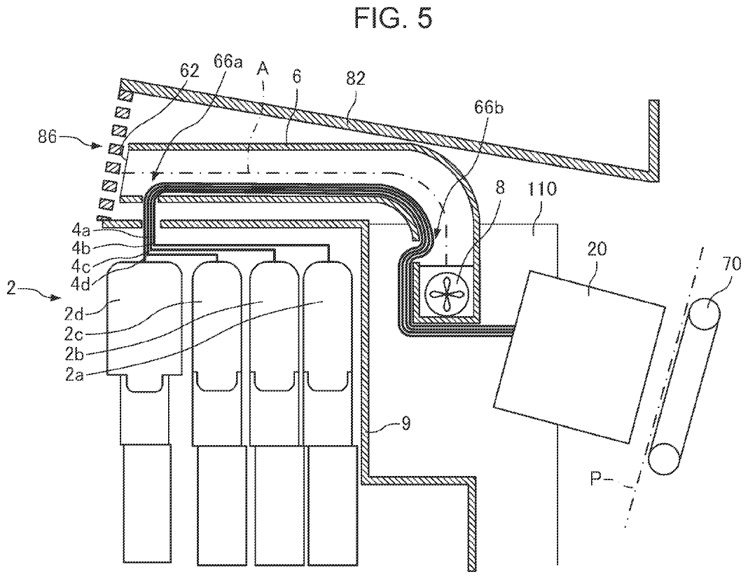

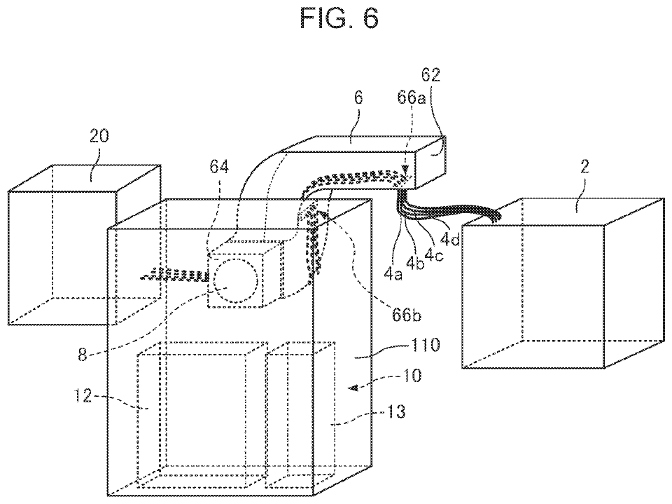

FIGS. 5 and 6 are diagrams for explaining a main part of the liquid ejecting apparatus 1.

As illustrated in FIGS. 5 and 6, the liquid ejecting apparatus 1 includes the duct 6, a fan 8, and a case 110 storing the control mechanism 10 including the power supply circuit 12 and the main control circuit 13. The duct 6, the fan 8, and the case 110 are housed in the housing 80.

The duct 6 is provided for cooling the control mechanism 10 as a heat generator. The duct 6 is a pipe that guides gas. The duct 6 has one end serving as an inlet 62 and the other end serving as an outlet 64. In the example illustrated in FIGS. 5 and 6, the duct 6 has a rectangular cross section. The shape of the duct 6 is not particularly limited. The material of the duct 6 is, for example, metal such as aluminum, plastic, or the like.

The inlet 62 of the duct 6 is disposed at the air inlet 86 of the housing 80. The outlet 64 of the duct 6 is disposed in the case 110 storing the control mechanism 10. The fan 8 is coupled to the outlet 64 of the duct 6. The duct 6 discharges, from the outlet 64, the gas drawn from the inlet 62. A path of the duct 6 is not particularly limited as long as the duct 6 guides the outside air from the air inlet 86 of the housing 80 to the inside of the case 110.

The fan 8 forms a flow of the gas in the duct 6. In the example illustrated in FIGS. 5 and 6, the fan 8 forms a flow of the gas from the inlet 62 of the duct 6 to the outlet 64 of the duct 6. Since the inlet 62 of the duct 6 is disposed at the air inlet 86 of the housing 80, the outside air can be drawn into the duct 6 from the air inlet 86 by the fan 8. Since the outlet 64 of the duct 6 is disposed in the case 110, the outside air can be discharged into the case 110 by the fan 8. As a result, it is possible to draw the outside air from the inlet 62 of the duct 6 into the duct 6 and discharge the drawn outside air into the case 110 from the outlet 64. Although not illustrated, the outside air supplied into the case 110 is discharged to the outside of the case 110 from a discharge port disposed in the case 110 and discharged to the outside of the housing 80 from a discharge port disposed in the housing 80.

Although the case where the gas that flows in the duct 6 is the outside air is described above, the gas that flows in the duct 6 is not limited to the outside air. For example, the gas that flows in the duct 6 may be air in the housing 80.

When the power supply circuit 12 and the main control circuit 13 operate, the power supply circuit 12 and the main control circuit 13 generate heat. That is, the control mechanism 10 including the power supply circuit 12 and the main control circuit 13 serves as the heat generator in the liquid ejecting apparatus 1. The duct 6 and the fan 8 are used to supply the gas into the case 110 and form a flow of the gas in the case 110. Therefore, the heat generator including the power supply circuit 12 and the main control circuit 13 can be cooled. In addition, the heat generator can be efficiently cooled by supplying, into the case 110, the outside air at a lower temperature than that of air in the case 110.

Although the case where the heat generator is the control mechanism 10 including the power supply circuit 12 and the main control circuit 13 described above, the heat generator is not limited to the control mechanism 10. The heat generator is not particularly limited as long as the heat generator is a heat generating source that generates heat when the heat generating source operates. The heat generating source may be, for example, another circuit other than the power supply circuit 12 and the main control circuit 13, a motor, or the like.

As illustrated in FIG. 5, the liquid storage section 2 includes a first container 2a in which ink of cyan C is stored, a second container 2b in which ink of magenta M is stored, a third container 2c in which ink of yellow Y is stored, and a fourth container 2d in which ink of black K is stored. Therefore, the ink stored in the liquid storage section 2 is supplied to the print head 20 through four tubes 4, that is, a tube 4a, a tube 4b, a tube 4c, and a tube 4d. The first container 2a, the second container 2b, the third container 2c, and the fourth container 2d are disposed in a space partitioned by a wall portion 9 in the housing 80. The ink stored in the liquid storage section 2 is, for example, a water-based ink containing water as a solvent, such as a water-based pigment or a water-based dye ink.

The tube 4a supplies the ink from the first container 2a to the print head 20. One end of the tube 4a is coupled to the first container 2a, and the other end of the tube 4a is coupled to the print head 20. The tube 4b supplies the ink from the second container 2b to the print head 20. One end of the tube 4b is coupled to the second container 2b, and the other end of the tube 4b is coupled to the print head 20. The tube 4c supplies the ink from the third container 2c to the print head 20. One end of the tube 4c is coupled to the third container 2c, and the other end of the tube 4c is coupled to the print head 20. The tube 4d supplies the ink from the fourth container 2d to the print head 20. One end of the tube 4d is coupled to the fourth container 2d, and the other end of the tube 4d is coupled to the print head 20. The tubes 4a, 4b, 4c, and 4d may be bundled together in such a way that the tubes 4a, 4b, 4c, and 4d are in contact with each other. Alternatively, the tubes 4a, 4b, 4c, and 4d may be separated from each other. The tube 4a is described below.

The material of the tube 4a is, for example, rubber, resin, or the like. The tube 4a is flexible. A portion of the tube 4a is disposed in the duct 6. The duct 6 has, formed therein, a first through-hole 66a penetrating through a wall portion of the duct 6, and a second through-hole 66b penetrating through a wall portion of the duct 6. The tube 4a enters the duct 6 through the first through-hole 66a and exits the duct 6 through the second through-hole 66b. That is, between the first through-hole 66a and the second through-hole 66b, the tube 4a is located in the duct 6.

At least the portion of the tube 4a that is located in the duct 6 is disposed along the flow of the gas in the duct 6. That is, at least the portion of the tube 4a that is located in the duct 6 is disposed along a central axis A of the duct 6. In the example illustrated in FIGS. 5 and 6, the portion of the tube 4a that is located in the duct 6 is disposed along the flow of the gas in the duct 6, that is, the portion of the tube 4a that is located in the duct 6 is disposed along the central axis A.

The gas flows from the inlet 62 toward the outlet 64 in the duct 6. The first through-hole 66a is located upstream of the flow of the gas in the duct 6 with respect to the second through-hole 66b. That is, in the path of the duct 6, a distance from the inlet 62 to the first through-hole 66a is shorter than a distance from the inlet 62 to the second through-hole 66b. Therefore, at least the portion of the tube 4a that is located in the duct 6 can be disposed along the flow of the gas in the duct 6.

Since the portion of the tube 4a is disposed in the duct 6, the ink flowing in the tube 4a can be cooled by the flow of the gas. In addition, since the outside air at a lower temperature than that of air in the housing 80 flows in the duct 6, the ink flowing in the tube 4a can be efficiently cooled.

The portion of the tube 4a that is located in the duct 6 is in contact with an inner surface of the duct 6. For example, when the material of the duct 6 is metal with high thermal conductivity, the ink flowing in the tube 4a in contact with the duct 6 can be efficiently cooled. The entire portion of the tube 4a disposed in the duct 6 may be in contact with the inner surface of the duct 6. In addition, a portion of the tube 4a is located outside the duct 6 and is in contact with an outer surface of the duct 6. Therefore, the ink flowing in the tube 4a outside the duct 6 can be cooled.

In the example illustrated in FIGS. 5 and 6, the portion of the tube 4a is disposed in the duct 6, but the entire tube 4a may be disposed in the duct 6 although not illustrated. In this case, a portion of the first container 2a may be disposed in the duct 6.

Although the tube 4a is described above, the same applies to the tubes 4b, 4c, and 4d, and a description of the tubes 4b, 4c, and 4d is omitted.

### 3. Operational Effects

The liquid ejecting apparatus 1 includes the print head 20 that ejects ink onto the medium P, the liquid storage section 2 that stores the ink, the tube 4a that supplies the ink from the liquid storage section 2 to the print head 20, the duct 6 in which gas flows, and the fan 8 that forms a flow of the gas in the duct 6. In the liquid ejecting apparatus 1, at least the portion of the tube 4a is in disposed in the duct 6. Thus, in the liquid ejecting apparatus 1, the ink flowing in the tube 4a can be cooled by the gas flowing in the duct 6. Therefore, in the liquid ejecting apparatus 1, it is possible to reduce an increase in the temperature of the ink and reduce a change in the characteristics of the ink due to a change in the temperature of the ink.

For example, when the ink flowing in the tube 4a is warmed by radiant heat from the heat generator or the like, and the temperature of the ink flowing in the tube 4a increases, the ink may evaporate and clog the print head 20, and the apparatus may fail. In addition, when the temperature of the ink increases, the lifetime of the ink may be shortened. In the liquid ejecting apparatus 1, since the ink flowing in the tube 4a can be cooled, it is possible to reduce a possibility that the apparatus may fail and it is possible to improve the lifetime of the ink.

The liquid ejecting apparatus 1 includes the housing 80 having the air inlet 86. The fan 8 draws the outside air into the duct 6 from the air inlet 86. Therefore, in the liquid ejecting apparatus 1, the ink flowing in the tube 4a can be cooled by the outside air drawn from the air inlet 86.

The liquid ejecting apparatus 1 includes the heat generator including the power supply circuit 12 and the main control circuit 13, and the duct 6 supplies the gas to the heat generator. Therefore, in the liquid ejecting apparatus 1, the heat generator including the power supply circuit 12 and the main control circuit 13 and the ink flowing in the tube 4a can be cooled. In the liquid ejecting apparatus 1, a cooling mechanism that includes a fan and a duct for cooling the ink flowing in the tube 4a and is dedicated to cooling ink is not required, and it is possible to downsize the apparatus, reduce the cost of the apparatus, and save electric power.

In the liquid ejecting apparatus 1, the print head 20 is the line head having the length equal to or longer than the width of the medium P. Therefore, in the liquid ejecting apparatus 1, the print head 20 does not move and thus it is possible to reduce a load of the tube 4a. For example, if the print head 20 moves, the tube 4a moves due to the movement of the print head 20 and a load is applied to the tube 4a. In the liquid ejecting apparatus 1, the print head 20 does not move and it is possible to reduce a load of the tube 4a, as compared with a case where the print head 20 moves.

In the liquid ejecting apparatus 1, at least the portion of the tube 4a that is located in the duct 6 is disposed along the flow of the gas in the duct 6. Therefore, in the liquid ejecting apparatus 1, the tube 4a located in the duct 6 can be made long and it is possible to efficiently cool the ink flowing in the tube 4a.

In the liquid ejecting apparatus 1, the ink that is supplied to the print head 20 through the tube 4a is a water-based ink. In the liquid ejecting apparatus 1, it is possible to reduce an increase in the temperature of the ink and thus it is possible to reduce a change in the characteristics of the ink due to a change in the temperature of the ink even when the water-based ink that is sensitive to temperature is used.

In the liquid ejecting apparatus 1, at least the portion of the tube 4a that is located in the duct 6 is in contact with the duct 6. Therefore, in the liquid ejecting apparatus 1, it is possible to efficiently cool the ink flowing in the tube 4a. In addition, it is possible to reduce an effect of the tube 4a on the flow of the gas in the duct 6, as compared with a case where the tube 4a is not in contact with an inner portion of the duct 6.

Although the operational effects of the liquid ejecting apparatus 1 are described above using the tube 4a as an example, operational effects that are the same as or similar to those described above can be obtained for the tubes 4b, 4c, and 4d.

### 4. Modifications

Although the embodiment describes the case where the tubes 4a, 4b, 4c, and 4c are disposed in the duct 6 to be used to cool the heat generator including the power supply circuit 12 and the main control circuit 13, the duct 6 in which the tubes 4a, 4b, 4c, and 4d are disposed is not limited to a duct for cooling the heat generator. For example, the duct 6 may be provided for collecting mist of the ink.

In the liquid ejecting apparatus 1, a part of the ink ejected from the print head 20 does not land on the medium P and floats in the air as mist. The mist may adhere to various portions and mechanisms in the liquid ejecting apparatus 1. If dirt caused by the mist accumulates, the dirt affects the operation of the liquid ejecting apparatus 1 and the quality of printing by the liquid ejecting apparatus 1. Therefore, although not illustrated, the inlet 62 of the duct 6 is disposed in a space in which the mist floats and the outlet 64 of the duct 6 is disposed in a mist collection container in the liquid ejecting apparatus 1. The fan 8 is disposed at the outlet 64 of the duct 6 and forms an air flow that guides the mist from the inlet 62 of the duct 6 to the outlet 64 of the duct 6. In this manner, the duct 6 and the fan 8 are used to collect the mist into the mist collection container.

The tube 4a, 4b, 4c, and 4d are disposed in the duct 6 for collecting mist. The ink flowing in the tube 4a, 4b, 4c, and 4d located in the duct 6 is cooled by the flow of the air in the duct 6.

In the liquid ejecting apparatus 1, the duct 6 may be provided for collecting mist of the ink. Therefore, the duct 6 can collect mist of the ink and cool the ink flowing in the tube 4a. In the liquid ejecting apparatus 1, a cooling mechanism that includes a fan and a duct for cooling the ink flowing in the tube 4a and is dedicated to cooling ink is not required, and it is possible to downsize the apparatus, reduce the cost of the apparatus, and save electric power. Even in the liquid ejecting apparatus 1 in which the duct 6 is provided for collecting mist of the ink, it is possible to obtain operational effects that are the same as or similar to those obtained when the duct 6 is provided for cooling the heat generator.

Although the embodiments and the modifications are described above, the present disclosure is not limited to the embodiments and can be implemented in various aspects without departing from the gist of the present disclosure. For example, the embodiments described above can be combined as appropriate.

The present disclosure includes substantially the same configurations (for example, a configuration in which functions, methods, and results are the same as those described above, or a configuration in which purposes and effects are the same as those described above) as the configurations described in the embodiments. In addition, the present disclosure includes a configuration in which a nonessential part of the configurations described in the embodiments is replaced. Furthermore, the present disclosure includes a configuration in which the same operational effects as those obtained in the configurations described in the embodiments are obtained, or a configuration in which the same purposes as those described in the embodiments are achieved. Furthermore, the present disclosure includes a configuration obtained by adding a known technique to the configurations described in the embodiments.

The following content is derived from the embodiments described above.

A liquid ejecting apparatus according to an aspect includes a print head that ejects liquid onto a medium, a liquid storage section that stores the liquid, a tube that supplies the liquid from the liquid storage section to the print head, a duct in which gas flows, and a fan that forms a flow of the gas in the duct, and at least a portion of the tube is disposed in the duct.

According to this liquid ejecting apparatus, it is possible to cool the liquid flowing in the tube by the gas flowing in the duct. Therefore, in the liquid ejecting apparatus, it is possible to reduce an increase in the temperature of the liquid and reduce a change in the characteristics of the liquid due to a change in the temperature of the liquid.

The liquid ejecting apparatus according to the aspect may include a housing having an air inlet, and the fan may draw outside air into the duct from the air inlet.

According to this liquid ejecting apparatus, the outside air can be drawn into the duct by the fan, and thus the liquid flowing in the tube can be cooled by the outer air.

The liquid ejecting apparatus according to the aspect may include a heat generator, and the duct may supply the gas to the heat generator.

According to this liquid ejecting apparatus, it is possible to cool the heat generator and the liquid flowing in the tube. In addition, according to this liquid ejecting apparatus, a cooling mechanism dedicated to cooling the liquid flowing in the tube is not required, and it is possible to downsize the apparatus, reduce the cost of the apparatus, and save electric power.

In the liquid ejecting apparatus according to the aspect, the duct may be provided for collecting mist of the liquid.

According to this liquid ejecting apparatus, it is possible to collect the mist and cool the liquid flowing in the tube. In addition, according to this liquid ejecting apparatus, a cooling mechanism dedicated to cooling the liquid flowing in the tube is not required, and it is possible to downsize the apparatus, reduce the cost of the apparatus, and save electric power.

In the liquid ejecting apparatus according to the aspect, the print head may be a line head having a length equal to or longer than a width of the medium.

According to this liquid ejecting apparatus, the print head does not move and thus it is possible to reduce a load of the tube.

In the liquid ejecting apparatus according to the aspect, at least the portion of the tube that is located in the duct may be disposed along the flow of the gas in the duct.

According to this liquid ejecting apparatus, the tube located in the duct can be made long. Therefore, according to this liquid ejecting apparatus, it is possible to efficiently cool the liquid flowing in the tube.

In the liquid ejecting apparatus according to the aspect, the liquid that is supplied to the print head through the tube may be a water-based ink.

According to this liquid ejecting apparatus, it is possible to reduce an increase in the temperature of the ink, and thus it is possible to reduce a change in the characteristics of the ink due to a change in the temperature of the ink even when the water-based ink that is sensitive to temperature is used.

In the liquid ejecting apparatus according to the aspect, at least the portion of the tube that is located in the duct may be in contact with the duct.

According to this liquid ejecting apparatus, it is possible to efficiently cool the liquid flowing in the tube.

What is claimed is:

1. A liquid ejecting apparatus comprising:
a print head that ejects liquid onto a medium;
a liquid storage section that stores the liquid;
a tube that supplies the liquid from the liquid storage section to the print head;
a duct in which gas flows; and
a fan that forms a flow of the gas in the duct, wherein
at least a portion of the tube is disposed in the duct.

2. The liquid ejecting apparatus according to claim 1, further comprising a housing having an air inlet, wherein the fan draws outside air into the duct from the air inlet.

3. The liquid ejecting apparatus according to claim 1, further comprising a heat generator, wherein the duct supplies the gas to the heat generator.

4. The liquid ejecting apparatus according to claim 1, wherein the duct is provided for collecting mist of the liquid.

5. The liquid ejecting apparatus according to claim 1, wherein the print head is a line head having a length equal to or longer than a width of the medium.

6. The liquid ejecting apparatus according to claim 1, wherein at least the portion of the tube that is located in the duct is disposed along the flow of the gas in the duct.

7. The liquid ejecting apparatus according to claim 1, wherein the liquid that is supplied to the print head through the tube is a water-based ink.

8. The liquid ejecting apparatus according to claim 1, wherein at least the portion of the tube that is located in the duct is in contact with the duct.
